(19) United States
(12) Patent Application Publication
(10) Pub. No.: US 2026/0214846 A1
(43) Pub. Date: Jul. 23, 2026

(54) SIDE ENTRY AND EXIT WATER-COOLING HEAT DISSIPATION DEVICE

(71) Applicant: Dongguan Xingku Cooling Technology Co., Ltd., Dongguan (CN)

(72) Inventors: Xiao Fan, Dongguan (CN); Haohui Tang, Dongguan (CN); Haoqiang Deng, Dongguan (CN)

(21) Appl. No.: 19/356,025

(22) Filed: Oct. 10, 2025

(30) Foreign Application Priority Data
Jan. 21, 2025 (CN) 202520141718.6

(51) Int. Cl. H05K 7/20

(52) U.S. Cl. CPC H05K 7/20272

(57) ABSTRACT

A side entry and exit water cooling and heat dissipation device is provided, which includes a first water chamber, a second water chamber arranged opposite to the first water chamber, and a plurality of heat dissipation channels provided between the first water chamber and the second water chamber; on an outer side of the heat dissipation channel, an inlet-and-outlet component is provided between the first water chamber and the second water chamber, a first water channel is communicated to the first water chamber, and a second water channel is communicated to the second water chamber. The inlet and outlet component is provided with an inlet port and an outlet port. The first water chamber is further provided with a partition. The side entry and exit water-cooling heat dissipation device can achieve side entry and exit water and ensure the heat dissipation efficiency.

### CROSS-REFERENCE TO RELATED APPLICATIONS

This application claims priority to Chinese Patent Application No. 202520141718.6, filed on January 21, 2025, which is hereby incorporated by reference in its entirety.

### TECHNICAL FIELD

The present disclosure relates to the field of water-cooling heat dissipation technologies, and in particular, to a side entry and exit water-cooling heat dissipation device.

### BACKGROUND

With the continuous improvement of electronic device performance, especially the widespread application of high-performance computers, servers, graphics cards and other devices, heat dissipation has become an important factor restricting device stability and performance. Traditional water-cooled cooling systems typically consist of cooling fans, water-cooled exhaust pipes, and other components. The water-cooled exhaust pipe uses a water inlet and outlet system, with coolant flowing from one end of the pipe to the other.

Although this design can meet the heat dissipation requirements to a certain extent, this water-cooled exhaust has high requirements for installation space and cannot be applied to small-scale installation scenarios. Although there are currently some water-cooled systems with side entry and exit water, the design of side entry and exit water can easily lead to uneven flow of coolant in the heat dissipation channel, resulting in poor heat dissipation in some areas and affecting the overall heat dissipation efficiency.

### SUMMARY

In order to overcome the shortcomings and deficiencies in the existing technology, the purpose of the present disclosure is to provide a side entry and exit water-cooling heat dissipation device, which can achieve side entry and exit water and ensuring the heat dissipation efficiency of the water-cooling heat dissipation device.

The present disclosure is implemented through the following technical solutions.

A side entry and exit water-cooling heat dissipation device, including a first water chamber, a second water chamber arranged opposite the first water chamber, and a plurality of heat dissipation channels provided between the first water chamber and the second water chamber, where on an outer side of the heat dissipation channels, an inlet-and-outlet component is provided between the first water chamber and the second water chamber, a first water channel is communicated to the first water chamber, and a second water channel is communicated to the second water chamber; the inlet-and-outlet component is provided with an inlet port communicated to the first water channel and an outlet port communicated to the second water channel, the first water chamber is further provided with a partition;

when liquid enters the first water chamber from the first water channel, it flows from one side of the first water chamber near the first water channel to the other side of the first water chamber under an obstruction of the partition, and flows in an opposite direction from the other side of the first water chamber to the plurality of heat dissipation channels.

Where the partition is provided in the first water chamber and divides the first water chamber into two layers, and a through hole is provided on one side of the partition away from the first water channel.

Where the heat dissipation channel is arranged side by side with the first water channel and the second water channel, a cross-section of the heat dissipation channel is rectangular; cross-sectional areas of both the first water channel and the second water channel are larger than that of the heat dissipation channel.

Where the first water channel and the second water channel are symmetrically arranged about the inlet-and-outlet component.

Where the inlet-and-outlet component, the first water channel, and the second water channel are externally connected with a cover plate.

Where a pressure relief valve is further provided on one side of the first water chamber near the first water channel.

The beneficial effects of the present disclosure are as follows.

The present disclosure provides a side entry and exit water-cooling heat dissipation device, which achieves the scene requirements of side entry and exit water by providing the first water channel, inlet-and-outlet component, and the second water channel between the first water chamber and the second water chamber. At the same time, the partition is provided in the first water chamber. When liquid enters the first water chamber from the first water channel, the liquid flows from the side of the first water chamber near the first water channel to the other side of the first water chamber under the obstruction of the partition, and flows in the opposite direction from the other side of the first water chamber to the plurality of heat dissipation channels, thereby achieving uniform flow of cooling liquid in the heat dissipation channels and improving the overall heat dissipation efficiency.

### BRIEF DESCRIPTION OF DRAWINGS

Further explanation of the present disclosure is provided using the accompanying drawings, but the embodiments shown in the drawings do not constitute any limitation on the present disclosure. For those skilled in the art, other drawings can be obtained based on the following drawings without creative work.

FIG. 1 is an exploded view of the present disclosure.

FIG. 2 is a sectional view of a first water chamber.

FIG. 3 is a sectional view of a first water channel, an inlet-and-outlet component, and a second water channel.

Numeral reference: first water chamber -101, second water chamber -102, heat dissipation channel -103, inlet-and-outlet component -104, first water channel -105, second water channel -106, partition -107, through-hole -108, cover plate -109, pressure relief valve -110, inlet port -111, outlet port -112.

### DESCRIPTION OF EMBODIMENTS

In order to make the above objectives, features, and advantages of the present disclosure more obvious and understandable, the specific implementation mode of the present disclosure will be described in detail below in combination with the accompanying drawings. Many specific details are elaborated in the following description to facilitate a full understanding of the present disclosure. However, the present disclosure can be implemented in many different ways than described herein, and those skilled in the art can make similar improvements without violating the connotation of the present disclosure. Therefore, the present disclosure is not limited by the specific embodiments disclosed below.

In the description of the present disclosure, it should be understood that terms “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “radial”, “circumference” and other terms are based on the directional or positional relationships shown in the accompanying drawings, and are only for the convenience of describing the present disclosure and simplifying the description, rather than indicating or implying that the device or component referred to must have a specific orientation, be constructed and operated in a specific orientation, and therefore cannot be understood as limiting the present disclosure.

In addition, terms “first” and “second” are only used for descriptive purposes and cannot be understood as indicating or implying relative importance or implying the number of technical features indicated. Therefore, the features that are limited to “first” and “second” can explicitly or implicitly include at least one of these features. In the description of the present disclosure, “multiple” means at least two, such as two, three, etc., unless otherwise specified.

With the continuous improvement of electronic device performance, especially the widespread application of high-performance computers, servers, graphics cards and other devices, heat dissipation has become an important factor restricting device stability and performance. Traditional water-cooled cooling systems typically consist of cooling fans, water-cooled exhaust pipes, and other components. The water-cooled exhaust pipe uses a water inlet and outlet system, with coolant flowing from one end of the pipe to the other.

Although this design can meet the heat dissipation requirements to a certain extent, this water-cooled exhaust has high requirements for installation space and cannot be applied to small-scale installation scenarios. Although there are currently some water-cooled systems with side entry and exit water, the design of side entry and exit water can easily lead to uneven flow of coolant in the heat dissipation channel, resulting in poor heat dissipation in some areas and affecting the overall heat dissipation efficiency.

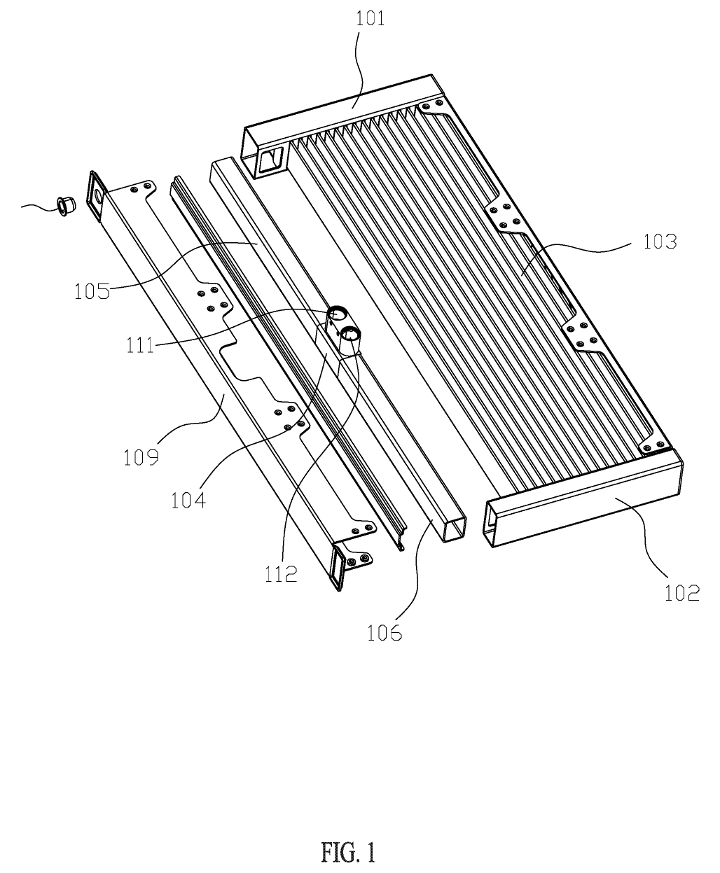

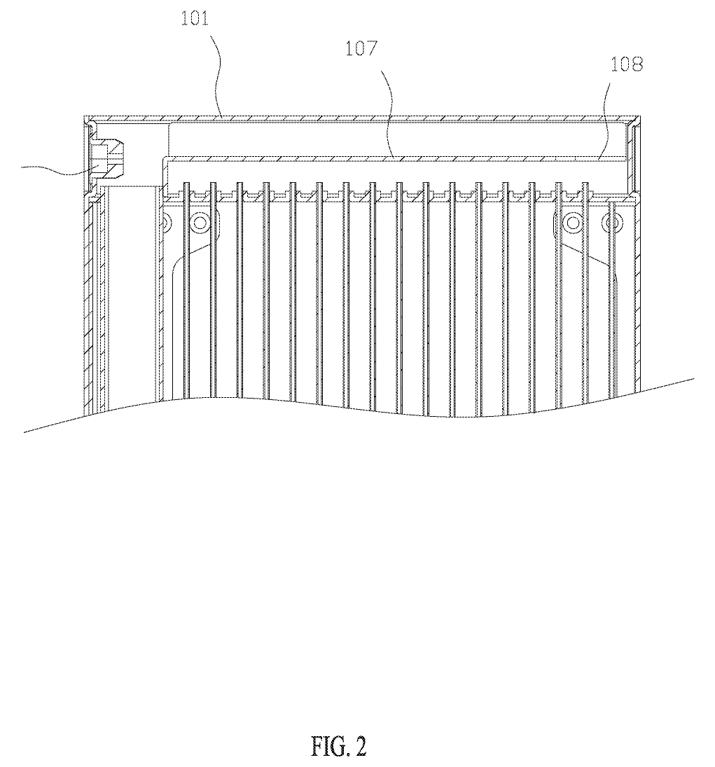

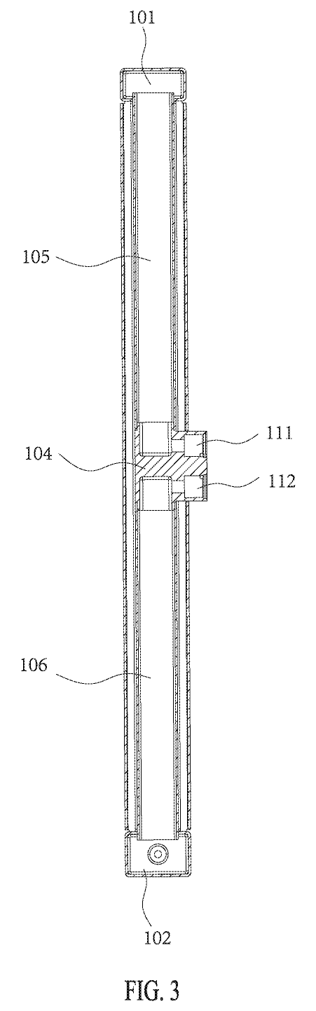

In order to solve the above problems, this embodiment discloses a side entry and exit water-cooling heat dissipation device, the structure of which is shown in FIGS. 1 to 3. The heat dissipation device includes a first water chamber 101, a second water chamber 102 arranged opposite to the first water chamber 101, and a plurality of heat dissipation channels 103 communication between the first water chamber 101 and the second water chamber 102. Heat dissipation fins are arranged between adjacent heat dissipation channels 103, and the cooling liquid in the heat dissipation channels 103 is heat exchanged through the heat dissipation fins to achieve the heat dissipation effect of the heat dissipation device.

On an outer side of the heat dissipation channel 103, the first water chamber 101 and the second water chamber 102 are further connected with an inlet-and-outlet component 104, a first water channel 105 is communicated to the first water chamber 101, and a second water channel 106 is communicated to the second water chamber 102. The inlet-and-outlet component 104 is provided with an inlet port 111 communicated to the first water channel 105 and an outlet port 112 communicated to the second water channel 106, and a partition 107 is further provided inside the first water chamber 101. When liquid enters the first water chamber 101 from the first water channel 105, it flows from one side of the first water chamber 101 near the first water channel 105 to the other side of the first water chamber 101 under an obstruction of the partition 107, and flows in an opposite direction from the other side of the first water chamber 101 to the plurality of heat dissipation channels 103.

In this embodiment, the inlet-and-outlet component 104 is integrally formed structure. By providing the first water channel 105, inlet-and-outlet component 104, and second water channel 106 between the first water chamber 101 and the second water chamber 102, the scene requirements for side entry and exit water can be achieved. At the same time, the partition 107 is provided inside the first water chamber 101. In an implementation mode, the partition 107 is provided inside the first water chamber 101 and divides the first water chamber 101 into upper and lower layers. A through hole 108 is provided on one side of the partition 107 away from the first water channel 105. When liquid enters the first water chamber 101 from the first water channel 105, it flows from one side of the first water chamber 101 near the first water channel 105 to the other side of the first water chamber 101 under the obstruction of the partition 107, and flows in the opposite direction from the other side of the first water chamber 101 to the plurality of heat dissipation channels 103, thereby achieving uniform flow of cooling liquid in the heat dissipation channels 103 and improving the overall heat dissipation efficiency.

It should be noted that in this embodiment, only the inlet port 111 and outlet port 112 are named according to the flow direction. In a case of another flow direction, positions of the inlet port 111 and outlet port 112 are changed, and it does not affect a flow path of a coolant in the heat dissipation device.

Furthermore, the heat dissipation channel 103 is arranged side by side with the first water channel 105 and the second water channel 106. A cross-section of the heat dissipation channel 103 is rectangular, and cross-sectional areas of the first water channel 105 and the second water channel 106 are both larger than that of the heat dissipation channel 103, thereby ensuring the circulation efficiency of the cooling liquid. In an implementation mode, the first water channel 105 and the second water channel 106 are symmetrically arranged about the inlet-and-outlet component 104.

Furthermore, the inlet-and-outlet component 104, the first water channel 105, and the second water channel 106 are externally connected with a cover plate 109 to ensure the overall structural strength of the heat dissipation device.

Furthermore, a pressure relief valve 110 is further provided on one side of the first water chamber 101 near the first water channel 105, which can release pressure when the internal air pressure of the heat dissipation device is too high, thereby avoiding liquid leakage or explosion.

Finally, it should be noted that above embodiments are only used to illustrate the technical solution of the present disclosure, and not to limit the protection scope of the present disclosure. Although the present disclosure has been described in detail with reference to the preferred embodiments, those skilled in the art should understand that the technical solution of the present disclosure can be modified or equivalently replaced without departing from the essence and scope of the technical solution of the present disclosure.

What is claimed is:

1. A side entry and exit water-cooling heat dissipation device, comprising a first water chamber, a second water chamber arranged opposite the first water chamber, and a plurality of heat dissipation channels provided between the first water chamber and the second water chamber,
wherein on an outer side of the heat dissipation channels, an inlet-and-outlet component is provided between the first water chamber and the second water chamber, a first water channel is communicated to the first water chamber, and a second water channel is communicated to the second water chamber; the inlet-and-outlet component is provided with an inlet port communicated to the first water channel and an outlet port communicated to the second water channel, the first water chamber is further provided with a partition;
when liquid enters the first water chamber from the first water channel, it flows from one side of the first water chamber near the first water channel to the other side of the first water chamber under an obstruction of the partition, and flows in an opposite direction from the other side of the first water chamber to the plurality of heat dissipation channels.

2. The side entry and exit water-cooling heat dissipation device according to claim 1, wherein the partition is provided in the first water chamber and divides the first water chamber into two layers, and a through hole is provided on one side of the partition away from the first water channel.

3. The side entry and exit water-cooling heat dissipation device according to claim 1, wherein the heat dissipation channel is arranged side by side with the first water channel and the second water channel,
a cross-section of the heat dissipation channel is rectangular;
cross-sectional areas of both the first water channel and the second water channel are larger than that of the heat dissipation channel.

4. The side entry and exit water-cooling heat dissipation device according to claim 1, wherein the first water channel and the second water channel are symmetrically arranged about the inlet-and-outlet component.

5. The side entry and exit water-cooling heat dissipation device according to claim 1, wherein the inlet-and-outlet component, the first water channel, and the second water channel are externally connected with a cover plate.

6. The side entry and exit water-cooling heat dissipation device according to claim 1, wherein a pressure relief valve is further provided on one side of the first water chamber near the first water channel.
